(19) United States
(12) Patent Application Publication
(10) Pub. No.: US 2021/0351017 A1
(43) Pub. Date: Nov. 11, 2021

(54) VAPOR DEPOSITION BAFFLE MECHANISM AND VAPOR DEPOSITION APPARATUS

(71) Applicant: Wuhan China Star Optoelectronics Semiconductor Display Technology Co., Ltd., Wuhan (CN)

(72) Inventors: Qiuhong Zhu, Wuhan (CN); Zhan Shi, Wuhan (CN)

(21) Appl. No.: 16/325,517

(22) PCT Filed: Nov. 28, 2018
(86) PCT No.: PCT/CN2018/117823

§ 371 Date: Feb. 14, 2019

(30) Foreign Application Priority Data
Nov. 5, 2018 (CN) 201811307079.7

(51) Int. Cl. H01J 37/32; C23C 14/24

(52) U.S. Cl. CPC H01J 37/32633; C23C 14/24; H01J 37/32449

(57) ABSTRACT

A vapor deposition baffle mechanism and a vapor deposition apparatus are provided. The vapor deposition baffle mechanism is disposed between a vapor deposition source and a substrate, and comprises a baffle component and a driving source. The vapor deposition aperture is configured to allow a substance evaporated from the vapor deposition source to pass through in a conical radiation manner and be deposited on a vapor deposition area of the substrate, and the driving source is configured to drive the baffle component to move upward to reduce the vapor deposition area of the substrate, or to drive the baffle component to move downward to enlarge the vapor deposition area of the substrate.

### FIELD OF INVENTION

The present disclosure relates to a vapor deposition baffle mechanism and a vapor deposition apparatus, and in particular to a vapor deposition baffle mechanism and a vapor deposition apparatus used in display manufacturing.

### BACKGROUND OF INVENTION

With rapid advancement of display technology, semiconductor component technology, which is the core of the display device, has also made great progress. For an existing display device, organic light emitting diodes (OLEDs) are used as a current type light emitting device. Because of characteristics of self-illumination, fast response, wide viewing angles, capable of being manufactured on a flexible substrate and the like, OLEDs have been used in high-performance displays more and more. In addition, OLED displays have many advantages such as bright colors, high contrast, low power consumption, softness, etc., and have become a hot spot in the development and investment of display fields. With the maturity of OLED display manufacturing technology, OLED displays are increasingly recognized by the public, and the application fields will become wider and wider.

In optoelectronic and display fields, particularly the field of manufacturing OLEDs, organic small molecule vacuum deposition nonuniformity resistance, the evaporation mask strength and accuracy requirements and other factors, the large scale of the OLED display technology to the development direction of the substrate. A vacuum vapor deposition apparatus of the prior art, regardless of the point evaporation source evaporation source, the evaporation source line, surface or the like evaporation source, vacuum deposition step are general, i.e. the film layers are deposited onto the entire substrate disposable.

In the OLED production technology, the equipment for evaporation is a vapor evaporation source, and the vapor evaporation source is further divided into an organic vapor evaporation source and an inorganic vapor evaporation source. There are differences in the design of evaporation sources for vapor deposition of different materials, and the design of the angle shield (angle limiting plate) is also different. In the current application, the length and height of the angle limiting plate of the design are fixed. However, the doping rates of different materials are different, and the corresponding angle limit plates are different, which is difficult to adjust the doping rate in production. Thus, the doping rate of the material impacts on the efficiency and life of the product.

### SUMMARY OF INVENTION

An object of the present disclosure is to provide a vapor deposition baffle mechanism and a vapor deposition apparatus. a driving source drives a baffle component to lift and lower for enlarging or reducing an evaporation area of a substrate, so that automatic adjustment of the height of the angle limiting plate can be achieved.

In order to solve the above problems, the technical solution provided by the present disclosure is as follows:

The present disclosure provides a vapor deposition baffle mechanism, the vapor deposition baffle mechanism is disposed between a vapor deposition source and a substrate, and the vapor deposition baffle mechanism comprises a baffle component and a driving source. The baffle component includes an angle limiting plate and a vapor deposition aperture, wherein the vapor deposition aperture is formed in the angle limiting plate, and the vapor deposition aperture is configured to allow a substance evaporated from the vapor deposition source to pass through in a conical radiation manner and be deposited on a vapor deposition area of the substrate. The driving source is mounted with the baffle component, wherein the driving source is configured to drive the baffle component to move upward to reduce the vapor deposition area of the substrate, or to drive the baffle component to move downward to enlarge the vapor deposition area of the substrate. The substrate is a glass substrate, and the driving source is configured to deposit a film on the glass substrate by vapor deposition.

In one embodiment of the present disclosure, the driving source includes two bases and two support rods, and the support rods are supported on opposite sides of the angle limiting plate, respectively.

In one embodiment of the present disclosure, the base is an automatic height adjuster, and the base is configured to lift and lower the support rod.

In one embodiment of the present disclosure, the base is an elastic adjuster, and the base is configured to lift and lower the support rod.

In one embodiment of the present disclosure, the base is a pneumatic rod or a hydraulic cylinder, and the base is configured to lift and lower the support rod.

In one embodiment of the present disclosure, the driving source includes two sliders mounted on the support rods to drive the angle limiting plate to move.

In one embodiment of the present disclosure, the support rod is marked with a scale, and the scale is configured to identify a height of a position of the angle limiting plate.

To achieve the above object of the present disclosure, an embodiment of the present disclosure provides a vapor deposition apparatus, and the vapor deposition apparatus comprises said vapor deposition baffle mechanism.

In one embodiment of the present disclosure, the vapor deposition apparatus further includes a cavity, and the vapor deposition baffle mechanism is disposed in the cavity.

In one embodiment of the present disclosure, the vapor deposition apparatus further includes a plurality of the vapor deposition sources and a plurality of the vapor deposition baffle mechanisms, and each of the vapor deposition baffle mechanisms is disposed above the corresponding vapor deposition source.

The present disclosure provides a vapor deposition baffle mechanism, the vapor deposition baffle mechanism is disposed between a vapor deposition source and a substrate, and the vapor deposition baffle mechanism comprises a baffle component and a driving source. The baffle component includes an angle limiting plate and a vapor deposition aperture, wherein the vapor deposition aperture is formed in the angle limiting plate, and the vapor deposition aperture is configured to allow a substance evaporated from the vapor deposition source to pass through in a conical radiation manner and be deposited on a vapor deposition area of the substrate. The driving source is mounted with the baffle component, wherein the driving source is configured to drive the baffle component to move upward to reduce the vapor deposition area of the substrate, or to drive the baffle component to move downward to enlarge the vapor deposition area of the substrate.

In one embodiment of the present disclosure, the driving source includes two bases and two support rods, and the support rods are supported on opposite sides of the angle limiting plate, respectively.

In one embodiment of the present disclosure, the base is an automatic height adjuster, and the base is configured to lift and lower the support rod.

In one embodiment of the present disclosure, the base is an elastic adjuster, and the base is configured to lift and lower the support rod.

In one embodiment of the present disclosure, the base is a pneumatic rod or a hydraulic cylinder, and the base is configured to lift and lower the support rod.

In one embodiment of the present disclosure, the driving source includes two sliders mounted on the support rods to drive the angle limiting plate to move.

In one embodiment of the present disclosure, the support rod is marked with a scale, and the scale is configured to identify a height of a position of the angle limiting plate.

The beneficial effect is that the driving source drives the baffle component to lift and lower for enlarging or reducing the evaporation area of the substrate, so that automatic adjustment of the height of the angle limiting plate can be achieved. When the height of the baffle component needs to be adjusted, the height of the angle limiting plate is adjusted by the driving source to change the size of the evaporation area of the substrate, thereby adjusting the doping ratio of the material. The efficiency and life of the vapor deposition apparatus can be improved.

### DESCRIPTION OF DRAWINGS

In order to more clearly illustrate the embodiments or prior art technical solutions embodiment of the present disclosure, will implement the following figures for the cases described in prior art or require the use of a simple introduction. Obviously, the following description of the drawings are only some of those of ordinary skill in terms of creative effort without precondition, you can also obtain other drawings based on these drawings embodiments of the present disclosure.

FIG. 1 is a schematic diagram of a baffle component moved downward of a vapor deposition apparatus according to a preferred embodiment of the present disclosure.

FIG. 2 is a schematic diagram of a baffle component moved upward of a vapor deposition apparatus according to a preferred embodiment of the present disclosure.

### DETAILED DESCRIPTION OF PREFERRED EMBODIMENTS

Structure and technical means adopted by the present disclosure to achieve the above and other objects can be best understood by referring to the following detailed description of the preferred embodiments and the accompanying drawings. Furthermore, directional terms described by the present disclosure, such as upper, lower, front, back, left, right, inner, outer, side, longitudinal/vertical, transverse/horizontal, etc., are only directions by referring to the accompanying drawings, and thus the used directional terms are used to describe and understand the present disclosure, but the present disclosure is not limited thereto.

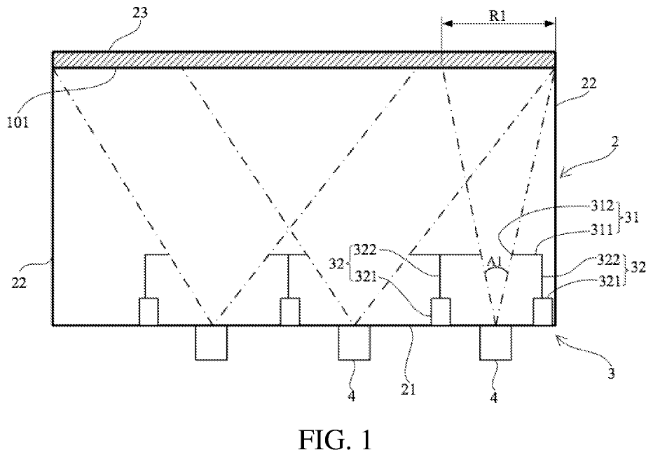

Referring to FIG. 1, a schematic diagram of a baffle component moved downward of a vapor deposition apparatus according to a preferred embodiment of the present disclosure is illustrated. The vapor deposition apparatus comprises a cavity 2, a plurality of the vapor deposition baffle mechanism 3, and a plurality of the vapor deposition sources 4. In a field of organic light-emitting diodes, the vapor deposition apparatus is configured to deposit a film on a substrate 101, such as a glass substrate, by vapor deposition, and the substrate 101 is disposed in the cavity 2. The detailed structure of each component, assembly relationships, and principles of operation for the present invention will be described in detail hereinafter.

Referring to FIG. 1, the cavity 2 includes a bottom plate 21, two side plates 22, and a top plate 23, wherein the two side plates 22 are disposed on opposite sides of the bottom plate 21, the top plate 23 covers the bottom plate 21 and is assembled with the two side plates 22, and the substrate 101 is disposed on the top plate 23.

Referring to FIG. 1, the vapor deposition baffle mechanisms 3 are disposed between the vapor deposition sources 4 and the substrate 101, and each of the vapor deposition baffle mechanisms 3 includes a baffle component 31 and a driving source 32. In the embodiment, the vapor deposition baffle mechanisms 3 are arranged side by side in the cavity 2. Each of the vapor deposition baffle mechanisms 3 is disposed above the corresponding vapor deposition source 4. In other embodiments, only one vapor deposition baffle mechanism 3 and one vapor deposition source 4 are disposed in the cavity 2, and they are not limited.

Referring to FIG. 1, the baffle component 31 includes an angle limiting plate 311 and a vapor deposition aperture 312, wherein the vapor deposition aperture 312 is formed in the angle limiting plate 311, and the vapor deposition aperture 312 is configured to allow a substance evaporated from the vapor deposition source 4 to pass through in a conical radiation manner and be deposited on a vapor deposition area of the substrate 101. In addition, the driving source 32 is mounted with the baffle component 31, wherein the driving source 32 is configured to drive the baffle component 31 to move upward to reduce the vapor deposition area of the substrate 101, or to drive the baffle component 31 to move downward to enlarge the vapor deposition area of the substrate 101.

Referring to FIG. 1, the driving source 32 includes two bases 321 and two support rods 322, and the support rods 322 are supported on opposite sides of the angle limiting plate 311, respectively. In the embodiment, the base 321 is an automatic height adjuster, and the base 321 is configured to lift and lower the support rod 322 in a direction, such as Z axis. In other embodiments, the base 321 is an elastic adjuster, and the base 321 is configured to lift and lower the support rod 322; or the base 321 is a pneumatic rod or a hydraulic cylinder, and the base 321 is configured to lift and lower the support rod 322; or the driving source 32 includes two sliders (not shown) mounted on the support rods 322 to drive the angle limiting plate 311 to move. Furthermore, the support rod 322 is marked with a scale, and the scale is configured to identify a height of a position of the angle limiting plate 311.

Referring to FIG. 1, the vapor deposition apparatus adopts a method of a spot evaporation source. For example, a plurality of the vapor deposition sources 4 are arranged side by side in the bottom plate 21 of the cavity 2 such that the vapor deposition sources 4 are located below the substrate 101, and the vapor deposition baffle mechanisms 3 are disposed between the substrate 101 and the vapor deposition sources 4.

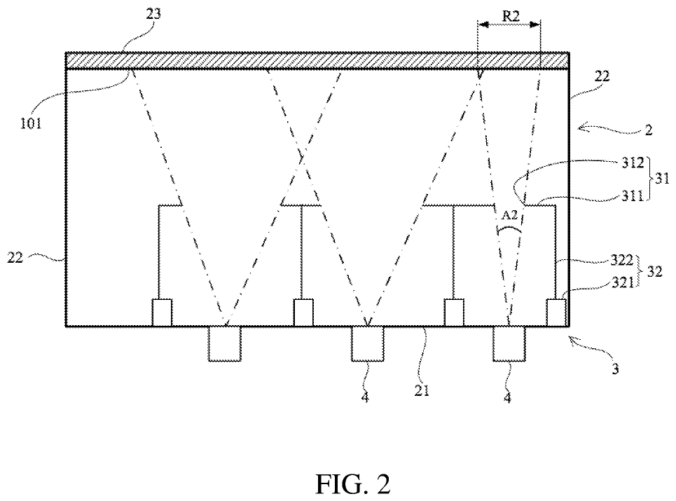

According to the above structure, the vapor deposition baffle mechanisms are not activated before vapor deposition. In operation, the material to be evaporated is placed in the vapor deposition sources 4 and heated. The substrate 101 rotates in a horizontal direction centering on its own geometric center. When the steam injection speed reaches a set value, the material evaporated from the evaporation sources 4 is attached to the substrate 101 through the corresponding vapor deposition apertures 312. As shown in FIG. 2, when an evaporation area R2 of the substrate 101 is reduced to reduce the doping ratio of the material, the baffle component 31 is driven to move upward by the driving source 32, and then a substance evaporated by the vapor deposition source 4 radiates in a conical shape. An evaporation angle A2 of the conical shape is limited. As shown in FIG. 1, when an evaporation area R1 of the substrate 101 is expanded to increase the doping ratio of the material, the baffle component 31 is driven to move downward by the driving source 32, and then a substance evaporated by the vapor deposition source 4 radiates in a conical shape. An evaporation angle A1 of the conical shape is enlarged. The change of the evaporation angle A1 to the evaporation angle A2 is achieved by automatic adjustment of the height of the angle limiting plate 311, so that the evaporation areas R1 to the evaporation areas R2 of the corresponding material are changed. Thereby, the doping ratio can be adjusted. Finally, when the vapor deposition material forms a film layer having a predetermined thickness on the substrate 101, the vapor deposition sources 4 are turned off to complete the operation on the substrate 101.

As described above, the driving source 32 drives the baffle component 31 to lift and lower for enlarging or reducing the evaporation area of the substrate 101, so that automatic adjustment of the height of the angle limiting plate 311 can be achieved. When the height of the baffle component 31 needs to be adjusted, the height of the angle limiting plate 311 is adjusted by the driving source 32 to change the size of the evaporation area of the substrate 101, thereby adjusting the doping ratio of the material. The efficiency and life of the vapor deposition apparatus can be improved.

The present disclosure has been described with preferred embodiments thereof and it is understood that many changes and modifications to the described embodiments can be carried out without departing from the scope and the spirit of the invention that is intended to be limited only by the appended claims.

1. A vapor deposition baffle mechanism disposed between a vapor deposition source and a substrate, comprising:
a baffle component including an angle limiting plate and a vapor deposition aperture, wherein the vapor deposition aperture is formed in the angle limiting plate, and the vapor deposition aperture is configured to allow a substance evaporated from the vapor deposition source to pass through in a conical radiation manner and be deposited on a vapor deposition area of the substrate; and
a driving source mounted with the baffle component, wherein the driving source is configured to drive the baffle component to move upward to reduce the vapor deposition area of the substrate, or to drive the baffle component to move downward to enlarge the vapor deposition area of the substrate;
wherein the substrate is a glass substrate, and the driving source is configured to deposit a film on the glass substrate by vapor deposition.

2. The vapor deposition baffle mechanism according to claim 1, wherein the driving source includes two bases and two support rods, and the support rods are supported on opposite sides of the angle limiting plate, respectively.

3. The vapor deposition baffle mechanism according to claim 2, wherein the base is an automatic height adjuster, and the base is configured to lift and lower the support rod.

4. The vapor deposition baffle mechanism according to claim 2, wherein the base is an elastic adjuster, and the base is configured to lift and lower the support rod.

5. The vapor deposition baffle mechanism according to claim 2, wherein the base is a pneumatic rod or a hydraulic cylinder, and the base is configured to lift and lower the support rod.

6. The vapor deposition baffle mechanism according to claim 2, wherein the driving source includes two sliders mounted on the support rods to drive the angle limiting plate to move.

7. The vapor deposition baffle mechanism according to claim 2, wherein the support rod is marked with a scale, and the scale is configured to identify a height of a position of the angle limiting plate.

8. A vapor deposition apparatus, comprising the vapor deposition baffle mechanism according to claim 1.

9. The vapor deposition apparatus according to claim 8, wherein the vapor deposition apparatus further includes a cavity, and the vapor deposition baffle mechanism is disposed in the cavity.

10. The vapor deposition apparatus according to claim 9, wherein the vapor deposition apparatus further includes a plurality of the vapor deposition sources and a plurality of the vapor deposition baffle mechanisms, and each of the vapor deposition baffle mechanisms is disposed above the corresponding vapor deposition source.

11. A vapor deposition baffle mechanism disposed between a vapor deposition source and a substrate, comprising:
a baffle component including an angle limiting plate and a vapor deposition aperture, wherein the vapor deposition aperture is formed in the angle limiting plate, and the vapor deposition aperture is configured to allow a substance evaporated from the vapor deposition source to pass through in a conical radiation manner and be deposited on a vapor deposition area of the substrate; and
a driving source mounted with the baffle component, wherein the driving source is configured to drive the baffle component to move upward to reduce the vapor deposition area of the substrate, or to drive the baffle component to move downward to enlarge the vapor deposition area of the substrate.

12. The vapor deposition baffle mechanism according to claim 11, wherein the driving source includes two bases and two support rods, and the support rods are supported on opposite sides of the angle limiting plate, respectively.

13. The vapor deposition baffle mechanism according to claim 12, wherein the base is an automatic height adjuster, and the base is configured to lift and lower the support rod.

14. The vapor deposition baffle mechanism according to claim 12, wherein the base is an elastic adjuster, and the base is configured to lift and lower the support rod.

15. The vapor deposition baffle mechanism according to claim 12, wherein the base is a pneumatic rod or a hydraulic cylinder, and the base is configured to lift and lower the support rod.

16. The vapor deposition baffle mechanism according to claim 12, wherein the driving source includes two sliders mounted on the support rods to drive the angle limiting plate to move.

17. The vapor deposition baffle mechanism according to claim 12, wherein the support rod is marked with a scale, and the scale is configured to identify a height of a position of the angle limiting plate.
